(19) United States
(12) Patent Application Publication
(10) Pub. No.: US 2013/0269465 A1
(43) Pub. Date: Oct. 17, 2013

(54) ROBOT AND ROBOT INSTALLATION METHOD

(71) Applicant: KABUSHIK KAISHA YASKAWA DENKI, kitayshu-shi (JP)

(72) Inventors: Nobuyuki FURUKAWA, Kitakyushu-shi (JP); Yuuki OHARA, Kitakyushu-shi (JP)

(21) Appl. No.: 13/647,738

(22) Filed: Oct. 9, 2012

(30) Foreign Application Priority Data
Dec. 19, 2011 (JP) 2011-277454

(51) Int. Cl. H01L 21/677

(52) U.S. Cl. CPC H01L 21/67742
USPC 74/490.01; 414/800

(57) ABSTRACT

A robot includes a base unit hoisted up from below a bottom surface portion of a chamber defining a work space and connected to the bottom surface portion of the chamber. The robot further includes an arm unit carried into the chamber from above the chamber and connected to an upper portion of the base unit connected to the bottom surface portion of the chamber.

### CROSS-REFERENCE TO RELATED APPLICATIONS

The present disclosure contains subject matter related to that disclosed in Japanese Priority Patent Application No. 2011-277454 filed with the Japan Patent Office on Dec. 19, 2011, the entire contents of which are incorporated herein by reference.

### BACKGROUND OF THE INVENTION

1. Field of the Invention

An embodiment disclosed herein relates to a robot and a robot installation method.

2. Description of the Related Art

A transfer robot for transferring a workpiece such as a substrate or the like is conventionally known as an industrial robot. As the transfer robot, there is known, e.g., a horizontal articulated robot configured to expand and contract in the horizontal direction. The horizontal articulated robot includes an arm unit provided at its tip end with a hand for holding a workpiece.

The transfer robot is used in, e.g., a semiconductor manufacturing apparatus or a liquid crystal panel manufacturing apparatus, to transfer a workpiece such as a semiconductor wafer or a glass substrate. In this apparatus, it is often the case that the workpiece is processed within a depressurized vacuum chamber. For that reason, the transfer robot is often arranged within the vacuum chamber.

The transfer robot is called a vacuum robot (see, e.g., Japanese Patent Application Publication No. 2011-101912). In case where the transfer robot (vacuum robot) is mounted within the vacuum chamber, it is typical that the transfer robot is lifted up through the use of a ceiling crane and is moved to above the vacuum chamber. Then, the transfer robot is lowered down and is put into the vacuum chamber.

In recent years, workpieces such as a glass substrate and a semiconductor wafer grow larger in size and accordingly a transfer robot and a vacuum chamber tend to become larger in size. This may possibly make it difficult to install the transfer robot within the vacuum chamber.

For example, the transfer robot tends to have an increased height as the size thereof grows larger. In order to position the large-size transfer robot above the vacuum chamber, it is therefore desirable to widen the space for carrying in the transfer robot, namely the space between the upper surface of the vacuum chamber and the ceiling surface of the room within which the vacuum chamber is installed. However, if the height of the transfer robot is increased, the height of the vacuum chamber for accommodating the transfer robot becomes larger but the height of the ceiling surface remains unchanged. This makes it difficult to widen the space for carrying in the transfer robot.

As stated above, if the transfer robot grows larger in size, it may possibly become difficult to install the transfer robot within the vacuum chamber.

### SUMMARY OF THE INVENTION

In accordance with one aspect of the present disclosure, there is provided a robot, including: a base unit hoisted up from below a bottom surface portion of a chamber defining a work space and connected to the bottom surface portion of the chamber; and an arm unit carried into the chamber from above the chamber and connected to an upper portion of the base unit connected to the bottom surface portion of the chamber.

### BRIEF DESCRIPTION OF THE DRAWINGS

FIG. 1 is a schematic explanatory view showing a robot according to an embodiment.

FIG. 2 is a schematic explanatory section view showing the robot installed within a vacuum chamber.

FIG. 3 is a schematic explanatory section view showing a body unit and an arm base.

FIG. 4 is a view comparing the height of the robot with the height of a space through which the robot is carried into the vacuum chamber.

FIG. 5A is an explanatory view illustrating a method of installing the body unit into the vacuum chamber.

FIG. 5B is an explanatory view illustrating another method of installing the body unit into the vacuum chamber.

FIG. 5C is an explanatory view illustrating a method of installing the arm unit into the vacuum chamber.

FIG. 6 is an explanatory view illustrating a method of roughly positioning the arm unit with respect to the body unit.

### DESCRIPTION OF THE EMBODIMENTS

A transfer robot for transferring a workpiece such as a substrate or the like is conventionally known as an industrial robot. As the transfer robot, there is known, e.g., a horizontal articulated robot configured to expand and contract in the horizontal direction. The horizontal articulated robot includes an arm unit provided at its tip end with a hand for holding a workpiece.

The transfer robot is used in, e.g., a semiconductor manufacturing apparatus or a liquid crystal panel manufacturing apparatus, to transfer a workpiece such as a semiconductor wafer or a glass substrate. In this apparatus, it is often the case that the workpiece is processed within a depressurized vacuum chamber. For that reason, the transfer robot is often arranged within the vacuum chamber. The transfer robot is called a vacuum robot (see, e.g., Japanese Patent Application Publication No. 2011-101912).

In case where the transfer robot (vacuum robot) is mounted within the vacuum chamber, it is typical that the transfer robot is lifted up through the use of a ceiling crane and is moved to above the vacuum chamber. Then, the transfer robot is lowered down and is put into the vacuum chamber.

In recent years, workpieces such as a glass substrate and a semiconductor wafer grow larger in size and accordingly a transfer robot and a vacuum chamber tend to become larger in size. This may possibly make it difficult to install the transfer robot within the vacuum chamber.

For example, the transfer robot tends to have an increased height as the size thereof grows larger. In order to position the large-size transfer robot above the vacuum chamber, it is therefore desirable to widen the space for carrying in the transfer robot, namely the space between the upper surface of the vacuum chamber and the ceiling surface of the room within which the vacuum chamber is installed. However, if the height of the transfer robot is increased, the height of the vacuum chamber for accommodating the transfer robot becomes larger but the height of the ceiling surface remains unchanged. This makes it difficult to widen the space for carrying in the transfer robot.

As stated above, if the transfer robot grows larger in size, it may possibly become difficult to install the transfer robot within the vacuum chamber.

### SUMMARY OF THE INVENTION

In accordance with one aspect of the present disclosure, there is provided a robot, including: a base unit hoisted up from below a bottom surface portion of a chamber defining a work space and connected to the bottom surface portion of the chamber; and an arm unit carried into the chamber from above the chamber and connected to an upper portion of the base unit connected to the bottom surface portion of the chamber.

### BRIEF DESCRIPTION OF THE DRAWINGS

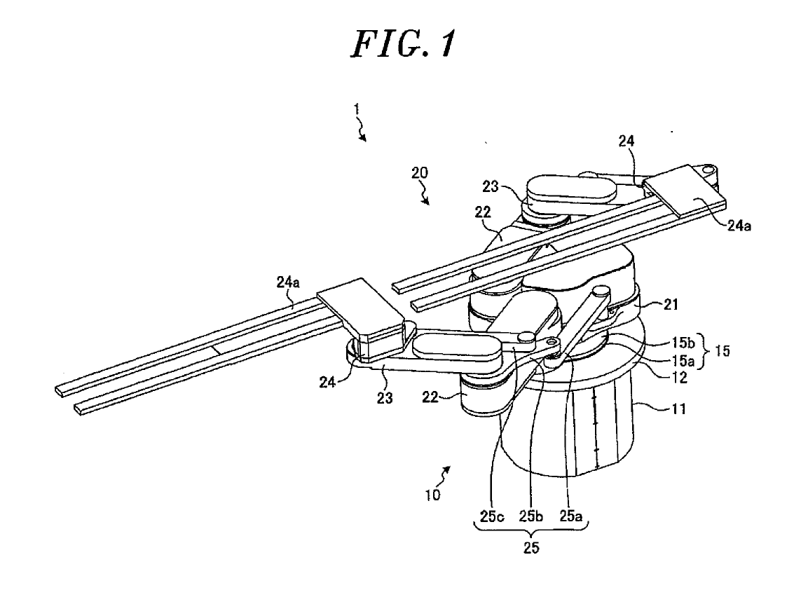

FIG. 1 is a schematic explanatory view showing a robot according to an embodiment.

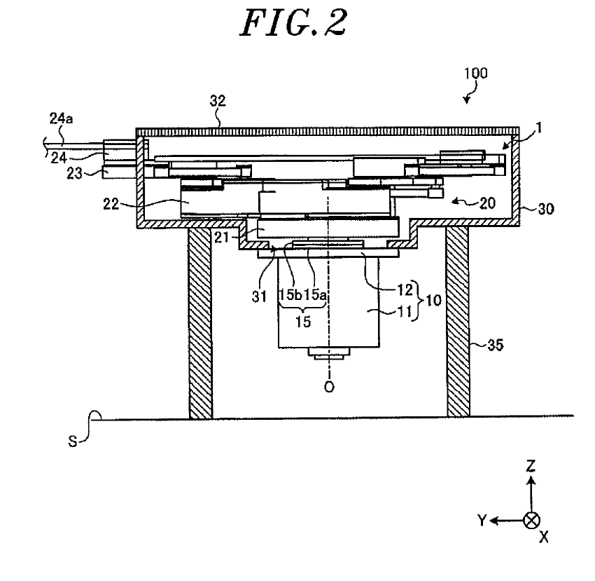

FIG. 2 is a schematic explanatory section view showing the robot installed within a vacuum chamber.

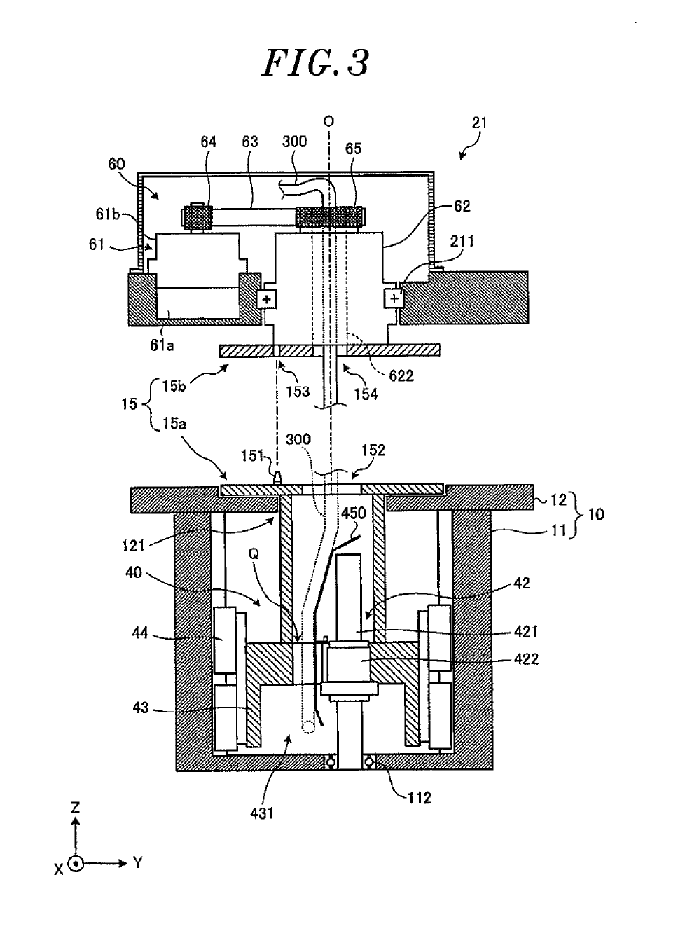

FIG. 3 is a schematic explanatory section view showing a body unit and an arm base.

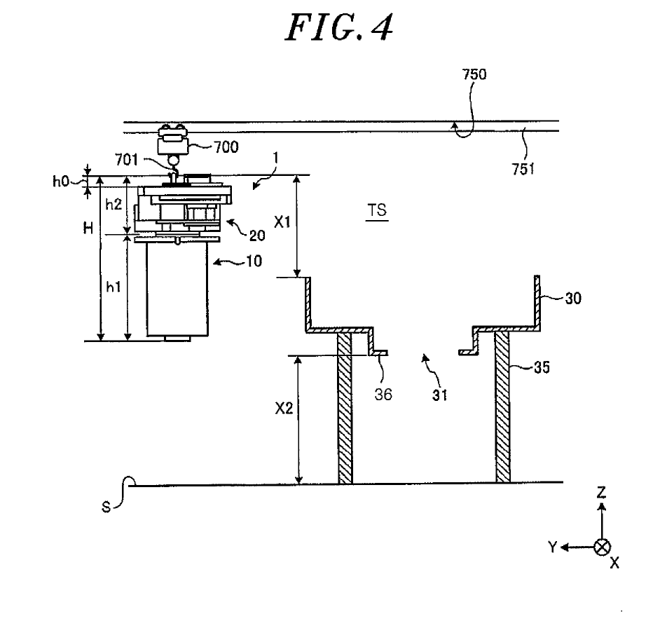

FIG. 4 is a view comparing the height of the robot with the height of a space through which the robot is carried into the vacuum chamber.

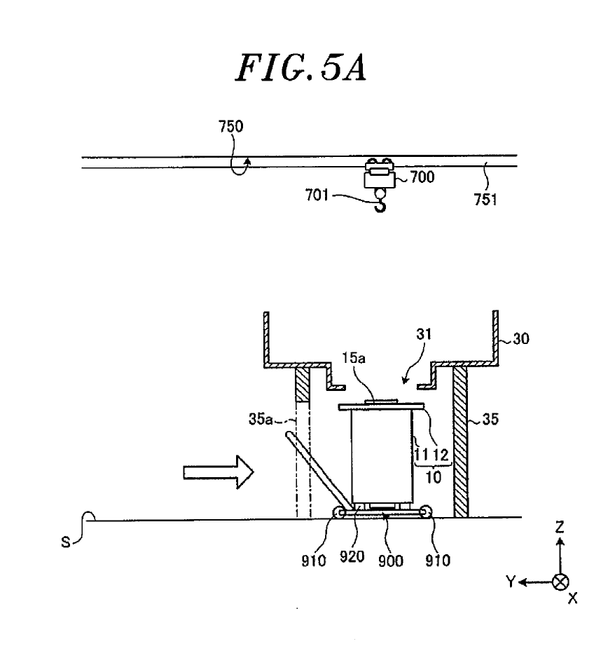

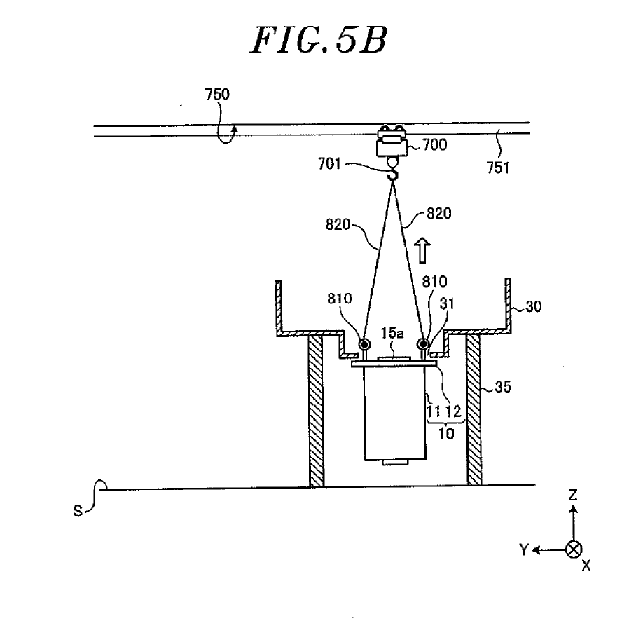

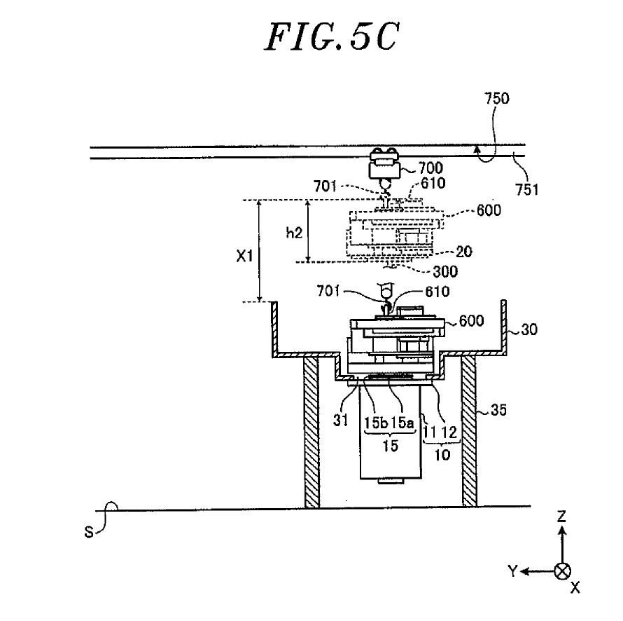

FIG. 5A is an explanatory view illustrating a method of installing the body unit into the vacuum chamber.

FIG. 5B is an explanatory view illustrating another method of installing the body unit into the vacuum chamber.

FIG. 5C is an explanatory view illustrating a method of installing the arm unit into the vacuum chamber.

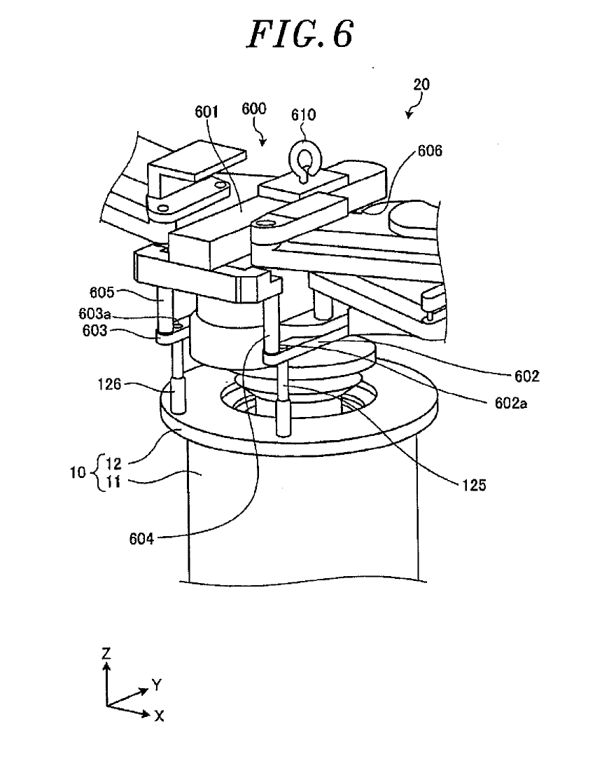

FIG. 6 is an explanatory view illustrating a method of roughly positioning the arm unit with respect to the body unit.

### DESCRIPTION OF THE EMBODIMENTS

Embodiments of a robot and a robot installation method disclosed herein will now be described in detail with reference to the accompanying drawings which form a part hereof. The present disclosure is not limited to the embodiment to be described below.

First, the configuration of the robot according to the present embodiment will be described with respect to FIG. 1. FIG. 1 is a schematic explanatory view showing the robot according to the embodiment.

As shown in FIG. 1, the robot 1 is a horizontal articulated robot that includes an arm unit 20 having two extendible arms capable of extending and retracting in the horizontal direction and a body unit 10 for supporting the arm unit 20. In the present embodiment, the body unit 10 makes up a base unit.

The body unit 10 includes a below-mentioned lifting device 40 (see FIG. 3) arranged within a tubular housing 11. The body unit 10 moves the arm unit 20 up and down along a vertical direction through the use of the lifting device 40. The lifting device 40 will be described later in more detail with reference to FIG. 3.

A flange portion 12 is formed in the upper portion of the housing 11. The flange portion 12 is connected by bolts or the like to the peripheral edge of an opening portion 31 as a unit-connecting opening formed in a vacuum chamber 30 (see FIG. 2) that defines a work space therein. As a result, the robot 1 is installed in the vacuum chamber 30. The above configuration will be described later in more detail with reference to FIG. 2. The method of mounting the body unit 10 to the vacuum chamber 30 will be described later in more detail with reference to FIGS. 5A through 5C.

The arm unit 20 is a unit connected to the body unit 10 through a lifting flange unit 15 to be described later. The arm unit 20 includes an arm base 21, a first arm 22, a second arm 23, a hand base 24, and an auxiliary arm portion 25.

The arm base 21 is rotatably supported on the lifting flange unit 15. The arm base 21 is provided with a swing device 60 (see FIG. 3) that includes a motor 61a, a speed reducer 61b, and a swinging shaft 62. The arm base 21 makes rotation through the use of the swing device 60. The configuration of the swing device 60 will be described later in more detail with reference to FIG. 3.

The first arm 22 has a base end portion rotatably connected to the upper portion of the arm base 21 through a speed reducer. The second arm 23 has a base end portion rotatably connected to an upper tip end portion of the first arm 22 through a speed reducer.

The hand base 24 is rotatably connected to a tip end portion of the second arm 23. A hand 24a as an end effector for holding a workpiece such as a glass substrate or a semiconductor wafer is provided in the upper portion of the hand base 24. The hand base 24 is moved by the rotating motion of the first arm 22 and the second arm 23.

The robot 1 is configured to linearly move the hand 24a by synchronously operating the speed reducer provided in the base end portion of the first arm 22 and the speed reducer provided in the tip end portion of the first arm 22, through the use of a single motor.

More specifically, the robot 1 rotates the first arm 22 and the second arm 23 such that the rotation amount of the second arm 23 with respect to the first arm 22 becomes twice as large as the rotation amount of the first arm 22 with respect to the arm base 21. For example, the first arm 22 and the second arm 23 are rotated such that, if the first arm 22 rotates α degree with respect to the arm base 21, the second arm 23 rotates 2α degrees with respect to the first arm 22. As a consequence, the hand 24a is moved linearly.

With a view to prevent contamination of the inside of the vacuum chamber 30, drive devices such as a motor and a speed reducer are arranged within the first arm 22 kept at the atmospheric pressure. Therefore, even if the robot 1 is kept under a depressurized environment, it is possible to prevent a lubricant such as grease or the like from getting dry and to prevent the inside of the vacuum chamber 30 from being contaminated by dirt.

The auxiliary arm portion 25 is a link mechanism that restrains rotation of the hand base 24 in conjunction with the rotating motion of the first arm 22 and the second arm 23 so that the hand 24a can always face a specified direction during its movement.

More specifically, the auxiliary arm portion 25 includes a first link 25a, an intermediate link 25b and a second link 25c.

The base end portion of the first link 25a is rotatably connected to the arm base 21. The tip end portion of the first link 25a is rotatably connected to the tip end portion of the intermediate link 25b. The base end portion of the intermediate link 25b is pivoted in a coaxial relationship with a connecting axis that interconnects the first arm 22 and the second arm 23. The tip end portion of the intermediate link 25b is rotatably connected to the tip end portion of the first link 25a.

The base end portion of the second link 25c is rotatably connected to the intermediate link 25b. The tip end portion of the second link 25c is rotatably connected to the base end portion of the hand base 24. The tip end portion of the hand base 24 is rotatably connected to the tip end portion of the second arm 23. The base end portion of the hand base 24 is rotatably connected to the second link 25c.

The first link 25a, the arm base 21, the first arm 22, and the intermediate link 25b make up a first parallel link mechanism. In other words, if the first arm 22 rotates about the base end portion thereof, the first link 25a rotates while keeping parallelism with the first arm 22.

When seen in a plan view, the connecting line interconnecting the connecting axis of the arm base 21 and the first arm 22 and the connecting axis of the arm base 21 and the second link 25a rotates while keeping parallelism with the intermediate link 25b.

The second link 25c, the second arm 23, the hand base 24 and the intermediate link 25b make up a second parallel link mechanism. In other words, if the second arm 23 rotates about the base end portion thereof, the second link 25c and the hand base 24 rotate while keeping parallelism with the second arm 23 and the intermediate link 25b, respectively.

The intermediate link 25b rotates while keeping parallelism with the aforementioned connecting line under the action of the first parallel link mechanism. For that reason, the hand base 24 of the second parallel link mechanism rotates while keeping parallelism with the arm base 21. As a result, the hand 24a mounted to the upper portion of the hand base 24 moves linearly while keeping parallelism with the aforementioned connecting line.

In this manner, the robot 1 can maintain the orientation of the hand 24a constant using two parallel link mechanisms, i.e., the first parallel link mechanism and the second parallel link mechanism. Therefore, as compared with, e.g., a case where pulleys and transmission belts are provided within the second arm 23 to maintain constant the orientation of an end effector using the pulleys and the transmission belts, it is possible to reduce generation of dirt attributable to the pulleys and the transmission belts.

Since the rigidity of the arm as a whole can be increased by the auxiliary arm portion 25, it is possible to reduce vibrations during the operation of the hand 24a. For that reason, as compared with a case where the orientation of an end effector is kept constant using pulleys and transmission belts, it is possible to reduce generation of dirt attributable to the vibrations generated during the operation of the hand 24a.

The arm unit 20 of the robot 1 according to the present embodiment includes two extendible arms, each of which includes the first arm 22, the second arm 23, the hand base 24 and the auxiliary arm portion 25. Therefore, the robot 1 can simultaneously perform two tasks, e.g., a task of taking out a workpiece from a transfer position using one of the extendible arms and a task of carrying a new workpiece into the transfer position using the other extendible arm.

Next, description will be made on one example of a semiconductor manufacturing apparatus that includes the robot 1 according to the present embodiment and the vacuum chamber 30 defining therein a work space of the robot 1. Thereafter, a method of installing the robot 1 within the vacuum chamber 30 will be described in detail.

FIG. 2 is a schematic explanatory section view showing one example of a semiconductor manufacturing apparatus 100. As shown in FIG. 2, the semiconductor manufacturing apparatus 100 includes the robot 1 and the vacuum chamber 30 for accommodating the robot 1.

The flange portion 12 formed in the body unit 10 of the robot 1 is fixed through a seal member (not shown) to the peripheral edge of the opening portion 31 formed in the substantially central region of the bottom of the vacuum chamber 30 installed on an installation surface S. Thus the vacuum chamber 30 is hermetically sealed and the inside of the vacuum chamber 30 is kept in a depressurized state by a depressurizing device such as a vacuum pump or the like. The housing 11 of the body unit 10 protrudes from the bottom of the vacuum chamber 30 and lies within a support portion 35 for supporting the vacuum chamber 30. While the support portion 35 is formed of a wall, it may be possible to form the support portion 35 with a plurality of legs.

The robot 1 performs a workpiece transferring task within the vacuum chamber 30. For example, the robot 1 linearly moves the hand 24a through the use of the first arm 22 and the second arm 23, thereby taking out a workpiece from another vacuum chamber connected to the vacuum chamber 30 through a gate valve not shown.

Subsequently, the robot 1 returns the hand 24a back and then horizontally rotates the arm base 21 about a swing axis O, thereby causing the arm unit 20 to directly face another vacuum chamber as the transfer destination of the workpiece. Then, the robot 1 linearly moves the hand 24a through the use of the first arm 22 and the second arm 23, thereby carrying the workpiece into another vacuum chamber as the transfer destination of the workpiece.

The vacuum chamber 30 is formed in conformity with the shape of the robot 1. For example, as shown in FIG. 2, a recess portion is formed in the bottom surface portion of the vacuum chamber 30. The portions of the robot 1 such as the arm base 21 and the lifting flange unit 15 are arranged in the recess portion. By forming the vacuum chamber 30 in conformity with the shape of the robot 1 in this manner, it is possible to reduce the internal volume of the vacuum chamber 30 and to readily keep the vacuum chamber 30 in a depressurized state.

A cover portion 32 for closing the vacuum chamber 30 in such a manner as to communicate with the outside is arranged in the upper portion of the vacuum chamber 30. As will be described later in more detail, the arm unit 20 of the robot 1 according to the present embodiment is brought into the vacuum chamber 30 from above the vacuum chamber 30 with the cover portion 32 removed.

In other words, the robot 1 according to the present embodiment is configured so that the body unit 10 and the arm unit 20 can be divided at the lifting flange unit 15.

More specifically, as shown in FIGS. 2 and 3, the lifting flange unit 15 of the robot 1 includes two flanges, namely a first docking flange 15a and a second docking flange 15b. The first docking flange 15a is fixed to the body unit 10. The second docking flange 15b is fixed to the arm unit 20. In the robot 1 according to the present embodiment, the body unit 10 and the arm unit 20 are unified by fastening the first docking flange 15a and the second docking flange 15b with bolts or the like.

In the present embodiment, the robot 1 is installed in the vacuum chamber 30 by dividing the robot 1 into the body unit 10 and the arm unit 20. This makes it possible to readily install the robot 1 in the vacuum chamber 30.

The body unit 10 having the first docking flange 15a and the arm base 21 having the second docking flange 15b will now be described with reference to FIG. 3. FIG. 3 is a schematic explanatory section view showing the body unit 10 and the arm base 21.

As shown in FIG. 3, the body unit 10 includes a lifting device 40 arranged therein. The lifting device 40 is a device for vertically moving a lifting shaft 43 through the use of a motor (not shown) and a converting mechanism 42. The first docking flange 15a is fixed to the upper end portion of the lifting shaft 43 protruding through a flange opening 121 formed in the flange portion 12.

The arm unit 12 includes a swing device 60. The swing device 60 serves to transmit the rotation of a reducer-motor assembly 61, which is formed by unifying a motor 61a and a speed reducer 61b, to a swinging shaft 62 through pulleys 64 and 65 and a transmission belt 63, thereby rotating the swinging shaft 62. The swinging shaft 62 is rotatably supported on the arm base 21 through a bearing 211 but is not fixed in the rotating direction. Consequently, the arm base 21 is horizontally rotated about a swing axis O, i.e., the center axis of the swinging shaft 62.

The second docking flange 15b is fixed to a tip end portion of the swinging shaft 62 protruding vertically downward from the lower portion of the arm base 21.

The body unit 10 and the arm unit 20 are combined into the robot 1 by fixing the first docking flange 15a and the second docking flange 15b with bolts or the like.

As shown in FIG. 3, a positioning pin 151 is provided on the upper surface of the first docking flange 15a and an engaging hole 153 engageable with the positioning pin 151 is formed in the second docking flange 15b. The arm unit 20 is connected to the body unit 10 in a suitable position by fixing the first docking flange 15a and the second docking flange 15b in a state that the positioning pin 151 and the engaging hole 153 are brought into engagement with each other.

In the robot 1 according to the present embodiment, the first docking flange 15a smaller in diameter than the body unit 10 is provided in the upper portion of the body unit 10. The second docking flange 15b substantially equal in diameter to the first docking flange 15a is provided in the lower portion of the arm unit 20. In the robot 1 according to the present embodiment, the body unit 10 and the arm unit 20 are unified by connecting the first docking flange 15a and the second docking flange 15b. This makes it possible to easily unify the body unit 10 and the arm unit 20 even if they are separated from each other.

In the robot 1 according to the present embodiment, the positioning pin 151 as a positioning protrusion is provided in the first docking flange 15a. The engaging hole 153 as a positioning recess engageable with the positioning pin 151 is formed in the second docking flange 15b. This makes it possible to connect the arm unit 20 to the body unit 10 in an accurate position.

In the present embodiment, the positioning pin 151 is provided in the first docking flange 15a and the engaging hole 153 is formed in the second docking flange 15b. Alternatively, a through-hole may be formed in the first docking flange 15a and a positioning pin may be provided in the second docking flange 15b. In the present embodiment, the positioning pin 151 and the engaging hole 153 are taken as examples of the positioning protrusion and the positioning recess. However, the positioning protrusion and the positioning recess are not limited to the pin and the hole.

In the present embodiment, description has been made on an instance where the swing device 60 is provided with the motor-reducer assembly 61. However, it is not always necessary to unify the motor and the speed reducer.

Next, the swing device 60 and the lifting device 40 will be described in detail. As shown in FIG. 3, the swinging shaft 62 of the swing device 60 has a through-hole 622 extending from the upper end of the swinging shaft 62 to the lower end thereof along the swing axis O. Likewise, the second docking flange 15b has a through-hole 154. A wiring cable 300 of the arm unit 20 is inserted through the through-holes 622 and 154. The wiring cable 300 extends from above the swinging shaft 62 to below the arm base 21 through the through-holes 622 and 154.

The lifting device 40 includes a converting mechanism 42, a lifting shaft 43 and a linear guide 44. The converting mechanism 42 is a mechanism for converting a rotary motion of a motor not shown to a linear motion. More specifically, the converting mechanism 42 includes a ball screw 421 and a ball nut 422. The ball screw 421 is rotatably supported on the housing 11 through a bearing 112. The ball nut 422 is threadedly coupled to the ball screw 421.

The lifting shaft 43 is a tubular member extending along the vertical direction. The converting mechanism 42 is arranged within the lifting shaft 43. The ball nut 422 of the converting mechanism 42 is fixed to the inner circumferential surface of the lifting shaft 43. The outer circumferential surface of the lifting shaft 43 is fixed to the linear guide 44.

Upon operating the motor not shown, the rotation of the motor is transmitted to the ball screw 421 of the converting mechanism 42 through a transmission belt and pulleys not shown. The rotary motion of the motor is converted to a linear motion by the ball screw 421 and the ball nut 422. Thus the lifting shaft 43 connected to the ball nut 422 is moved up and down along the linear guide 44.

The first docking flange 15a has a through-hole 152 extending along the swing axis O. The wiring cable 300 of the arm unit 20 is inserted into the lifting shaft 43 through the through-hole 152. The wiring cable 300 inserted into the lifting shaft 43 is led to the outside of the lifting shaft 43 from a cutout portion 431 formed in the lower portion of the lifting shaft 43 and is connected to a connector panel (not shown) provided outside the lifting shaft 43.

In this regard, the converting mechanism 42 is arranged close to the inner circumferential surface of the lifting shaft 43. More specifically, the converting mechanism 42 is arranged in an off-centered position such that the center axis of the ball screw 421 is deviated from the center axis of the lifting shaft 43 (i.e., the swing axis O). Accordingly, a wiring space Q for accommodation of the wiring cable 300 is formed between the converting mechanism 42 and the inner circumferential surface of the lifting shaft 43.

A guide member 450 for guiding the wiring cable 300 inserted from above toward the wiring space Q is provided within the lifting shaft 43. The guide member 450 is a member arranged between the wiring space Q and the converting mechanism 42 so as to cover the upper and side surfaces of the ball screw 421. The guide member 450 is inclined toward the wiring space Q.

By providing the guide member 450 within the lifting shaft 43 in this manner, it is possible to easily guide the wiring cable 300 toward the wiring space Q with no hindrance of the ball screw 421 and the ball nut 422. It is also possible to prevent the wiring cable 300 and the converting mechanism 42 from making contact with each other during the operation of the robot 1.

Next, description will be made on a method of installing the robot 1 in the vacuum chamber 30. FIG. 4 is a view comparing the height of the robot 1 with the height of a carrying-in space TS existing above the vacuum chamber 30. First, the comparison of the height H of the robot 1 with the height X1 of the carrying-in space TS formed between the vacuum chamber 30 and the ceiling 750 will be described with reference to FIG. 4. As shown in FIG. 4, the task of carrying the robot 1 into the vacuum chamber 30 is performed in a state that the cover portion 32 (see FIG. 2) is removed from the upper portion of the vacuum chamber 30.

The robot 1 is hoisted up through the use of, e.g., a ceiling crane 700. The ceiling crane 700 is a crane device capable of hoisting an object to a specified height using a hook 701, moving along a travel lane 751 provided on the ceiling 750 and lowering the hoisted object in a desired position.

In order to hoist the object with the ceiling crane 700 and the carry the object into the vacuum chamber 30, the height of the object needs to be smaller than the height X1 of the carrying-in space TS formed above the vacuum chamber 30. In this regard, the carrying-in space TS is a space through which the object, e.g., the robot 1, positioned above the vacuum chamber 30 is carried into the vacuum chamber 30. More specifically, the carrying-in space TS denotes a space between the lower end of the hook 701 lifted up to the highest position and the upper end of the vacuum chamber 30.

As shown in FIG. 4, the height H of the robot 1 according to the present embodiment is quite larger than the height X1 of the carrying-in space TS. In this case, even if an attempt is made to move the robot 1 toward the carrying-in space TS with the ceiling crane 700, the robot 1 comes into contact with the side wall of the vacuum chamber 30.

For that reason, the body unit 10 and the arm unit 20 of the robot 1 are divided and are individually carried into the vacuum chamber 30.

In the robot 1 according to the present embodiment, the height h2 of the arm unit 20 is smaller than the height X1 of the carrying-in space TS. However, the height h1 of the body unit 10 is larger than the height X1 of the carrying-in space TS. The height h2 of the arm unit 20 includes the distance h0 between the upper surface of the arm unit 20 and the lower end of the hook 701 of the ceiling crane 700.

Despite the fact that the robot 1 according to the present embodiment can be divided into the body unit 10 and the arm unit 20, it is impossible to carry the body unit 10 into the vacuum chamber 30 from above the vacuum chamber 30.

In the present embodiment, therefore, the body unit 10 is transferred from below the vacuum chamber 30 and the arm unit 20 is transferred from above the vacuum chamber 30. Thereafter, the body unit 10 and the arm unit 20 are connected to each other. Finally, the robot 1 is installed in the vacuum chamber 30. For that reason, the height h1 of the body unit 10 is set smaller than the height X2 from the installation surface S of the vacuum chamber 30 to the bottom surface portion 36 of the vacuum chamber 30.

As described above, the robot 1 according to the present embodiment includes the body unit 10 hoisted up from below the bottom surface portion 36 of the vacuum chamber 30 and connected to the bottom surface portion 36 of the vacuum chamber 30 and the arm unit 20 carried into the vacuum chamber 30 from above the vacuum chamber 30 and connected to an upper portion of the body unit 10 connected to the bottom surface portion 36 of the vacuum chamber 30.

Next, a method of installing the robot 1 according to the present embodiment in the vacuum chamber 30 will be described with reference to FIGS. 5A through 5C. FIGS. 5A and 5B are explanatory views illustrating a method of installing the body unit 10 in the vacuum chamber 30. FIG. 5C is an explanatory view illustrating a method of installing the arm unit 20 in the vacuum chamber 30.

As shown in FIG. 5A, the body unit 10 separated from the arm unit 20 is first mounted on a hand truck 900 having casters 910, and the hand truck 900 mounting thereon the arm unit 20 is moved to a position just below the opening portion 31 of the vacuum chamber 30. At this time, a portion of the support portion 35 positioned below the vacuum chamber 30 and formed of a wall may be configured in a removable manner and may be removed to form a carrying-in hole 35a when moving the body unit 10.

The upper attachment surface of the flange portion 12 of the body unit 10 and the surface for mounting a seal member such as an O-ring are cleaned in advance. In order to stably mount the body unit 10 on the hand truck 900, a spacer 920 is attached to the lower surface of the body unit 10.

A forklift may be suitably used as the hand truck 900. Alternatively, a rail extending to the center position of the vacuum chamber 30 may be laid on the installation surface S of the vacuum chamber 30 and a carriage capable of carrying the body unit 10 may be arranged to move back and forth along the rail.

In the manner described above, the body unit 10 is positioned just below the opening portion 31 of the bottom surface portion 36 of the vacuum chamber 30. In this position, the first docking flange 15a can face upward through the opening portion 31.

Next, eye bolts 810 as hoisting jigs are threadedly coupled to bolt holes previously formed in the flange portion 12 of the body unit 10. Thereafter, wires 820 suspending from the hook 701 of the ceiling crane 700 are locked to the ring portions of the eye bolts 810. In the present embodiment, four eyebolts 810 are used. The body unit 10 is hung by four wires 820.

As shown in FIG. 5B, the body unit 10 is hoisted up a little by the ceiling crane 700.

In this state, a worker can easily move the body unit 10. Therefore, the position alignment of the body unit 10 can be performed with ease. More specifically, the position alignment of the body unit 10 is performed by linearly moving the body unit 10 in the horizontal direction or rotating the body unit 10 in the horizontal direction so that the bolt insertion holes (not shown) formed in the flange portion 12 of the body unit 10 can be aligned with the connecting holes (not shown) formed in the peripheral edge portion of the opening portion 31 of the vacuum chamber 30.

Then, the flange portion 12 of the body unit 10 and the connecting holes formed in the peripheral edge of the opening portion 31 are connected and fixed to each other through the use of bolts. Eventually, the installation of the body unit 10 in the vacuum chamber 30 is completed. Guide members 125 and 126 (see FIG. 6) for positioning the arm unit 20 are mounted to the body unit 10 which is installed in the vacuum chamber 30. On the guide members 125 and 126, description will be made later with reference to FIG. 6.

If the installation of the body unit 10 in the vacuum chamber 30 is finished, the arm unit 20 is installed in the vacuum chamber 30 as shown in FIG. 5C.

First, a hanging jig 600 having a ring 610 is attached to the arm unit 20 separated from the body unit 10. Thereafter, the arm unit 20 is hoisted up after hooking the ring 610 with the hook 701 of the ceiling crane 700. At this time, the wiring cable 300 of the arm unit 20 is kept suspended from the lower portion of the arm unit 20.

Then, the ceiling crane 700 is caused to run along the travel lane 751, whereby the arm unit 20 is moved to the carrying-in space TS existing above the vacuum chamber 30. In this regard, the height h2 of the arm unit 20 including the hanging jig 600 is smaller than the height X1 of the carrying-in space TS as shown in FIG. 5C. Accordingly, the arm unit 20 can be moved to the carrying-in space TS and can be positioned above the center of the vacuum chamber 30 with no likelihood of contact with the vacuum chamber 30.

Subsequently, the ceiling crane 700 is operated to thereby lower the arm unit 20 toward the body unit 10 already installed in the vacuum chamber 30. At this time, the wiring cable 300 suspended from the lower portion of the arm unit 20 is inserted into the lifting shaft 43 of the lifting device 40 of the body unit 10 (see FIG. 3). As stated earlier, the guide member 450 is provided between the wiring space Q of the wiring cable 300 and the converting mechanism 42 within the lifting shaft 43. For that reason, the wiring cable 300 can extend through the wiring space Q with no hindrance of the converting mechanism 42.

Then, the arm unit 20 is further lowered such that the second docking flange 15b provided in the lower portion of the arm unit 20 comes close to the first docking flange 15a provided in the upper portion of the body unit 10.

In this regard, positioning marks making pairs with the guide members 125 and 126 provided in the body unit 10 are formed in the hanging jig 600. As will be described later, the worker performs a task of roughly positioning the arm unit 20 through the use of the guide members 125 and 126 and the positioning marks.

FIG. 6 is an explanatory view illustrating a method of roughly positioning the arm unit 20 with respect to the body unit 10. As shown in FIG. 6, cylindrical columnar guide members 125 and 126 are attached in specified positions on the flange portion 12 of the body unit 10. Through-holes 602a and 603a as positioning marks are formed in the hanging jig 600 of the arm unit 20 at the same interval as the interval between the guide members 125 and 126.

The worker performs a task of positioning the arm unit 20 using the guide members 125 and 126 and the through-holes 602a and 603a as positioning marks. More specifically, the worker lowers the arm unit 20 toward the body unit 10 while adjusting the position of the arm unit 20 so that, when the through-holes 602a and 603a are seen from above, the guide members 125 and 126 can lie within the through-holes 602a and 603a.

In the present embodiment, as set forth above, the positioning guide members 125 and 126 are removably attached to the flange portion 12 of the body unit 10. The through-holes 602a and 603a corresponding to the guide members 125 and 126 are formed in the hanging jig 600. In the present embodiment, the task of positioning the arm unit 20 with respect to the body unit 10 is performed through the use of the guide members 125 and 126 and the through-holes 602a and 603a. Accordingly, the worker can easily perceive the rough installation position of the arm unit 20 with respect to the body unit 10 while lowering the arm unit 20 toward the body unit 10.

As mentioned earlier, the positioning pin 151 as a positioning protrusion is provided in the first docking flange 15a of the body unit 10. The engaging hole 153 engageable with the positioning pin 151 is formed in the second docking flange 15b of the arm unit 20. This enables the worker to accurately install the second docking flange 15b with respect to the first docking flange 15a.

After the second docking flange 15b is placed on the first docking flange 15a, the worker fastens the first docking flange 15a and the second docking flange 15b with bolts or the like. As a consequence, the body unit 10 and the arm unit 20 are unified into the robot 1.

As shown in FIG. 6, the hanging jig 600 of the arm unit 20 includes an upper support member 601, lower support members 602 and 603, and connecting shafts 604 through 606. First, the lower support members 602 and 603 are attached to the lower portion of the arm base 21. The lower support members 602 and 603 attached to the arm base 21 partially protrude from the arm base 21 toward the negative side of the Y-axis. The through-holes 602a and 603a are respectively formed in the portions of the lower support members 602 and 603 protruding away the arm base 21.

Subsequently, the connecting shafts 604 and 605 are attached to the lower support members 602 and 603. The connecting shafts 606 is attached to the arm base 21. Then, the upper support member 601 is attached to the connecting shafts 604 through 606. The upper support member 601 and the connecting shafts 604 through 606 are fastened by bolts or the like. As a consequence, the hanging jig 600 is mounted to the arm unit 20.

Thereafter, the ceiling crane 700 is operated to lower the arm unit 20 toward the body unit 10 already installed in the vacuum chamber 30. The body unit 10 and the arm unit 20 are connected to each other. At this time, the positioning of the arm unit 20 is performed using the guide members 125 and 126 and the through-holes 602a and 603a as positioning marks. Then, the hanging jig 600, including the upper support member 601, the lower support members 602 and 603 and the connecting shafts 604 through 606, and the guide members 125 and 126 are removed to eventually finish the installation of the robot 1.

As described above, the robot 1 according to the present embodiment includes the body unit 10 hoisted up from below the bottom surface portion 36 of the vacuum chamber 30 and connected to the bottom surface portion 36 of the vacuum chamber 30. Moreover, the robot 1 includes the arm unit 20 carried into the vacuum chamber 30 from above the vacuum chamber 30 and connected to an upper portion of the body unit 10 connected to the bottom surface portion 36 of the vacuum chamber 30.

The robot 1 is installed in the vacuum chamber 30 by performing an installation method including the following two steps with respect to the vacuum chamber 30 having the work space and the unit-connecting opening portion 31 formed in the bottom surface portion 36.

The first step is a base unit connecting step of hoisting the body unit 10 as a base unit of the robot from below the bottom surface portion 36 of the vacuum chamber 30, connecting the body unit 10 to the bottom surface portion 36 of the vacuum chamber 30 and causing the upper surface of the flange portion 12 as a body unit connecting surface to face toward the opening portion 31.

The second step is an arm unit connecting step of carrying the arm unit 20 of the robot 1 into the vacuum chamber 30 from above the vacuum chamber 30, causing the arm unit 20 to face toward the body unit connecting surface through the opening portion 31, and connecting the arm unit 20 to the body unit 10 connected to the bottom surface portion 36 of the vacuum chamber 30.

With this method of installing the robot 1 in the vacuum chamber 30, it is possible to readily install even the robot 1 having an increased height in the vacuum chamber 30.

The base unit connecting step includes the following three steps. The first step is a transfer step of transferring the body unit 10 to below the bottom surface portion 36 of the vacuum chamber 30. The second step is a hoist step of hoisting up the body unit 10 transferred to below the bottom surface portion 36 of the vacuum chamber 30 through the opening portion 31 formed in the bottom surface portion 36 of the vacuum chamber 30. The third step is a positioning step of positioning the hoisted body unit 10 with respect to the bottom surface portion 36 of the vacuum chamber 30.

Accordingly, it is possible to easily and accurately connect and fix the body unit 10 to the bottom surface portion 36 of the vacuum chamber 30.

In the present embodiment, the sum of the height h1 of the body unit 10 and the height h2 of the arm unit 20 is set larger than the height X1 of the carrying-in space TS formed above the vacuum chamber 30. The height h1 of the body unit 10 is smaller than the height X2 from the installation surface S of the vacuum chamber 30 to the bottom surface portion 36 of the vacuum chamber 30 but is larger than the height X1 of the carrying-in space TS.

Accordingly, it becomes possible to easily install the robot 1 in the vacuum chamber 30, even if the robot 1 and the vacuum chamber 30 grows larger in size due to the increase in the height of the body unit 10, and even if a difficulty is involved in securing the carrying-in space TS between the vacuum chamber 30 and the ceiling 750.

In the foregoing embodiment, description has been made on an instance where the height H of the robot 1 is larger than the height X1 of the carrying-in space TS. Alternatively, the height H of the robot 1 may be smaller than the height X1 of the carrying-in space TS. Even in that case, the robot 1 is divided and carried into the vacuum chamber 30. It is therefore possible to reduce the weight and size of the object to be carried in by one carrying-in operation. It is also possible to easily carry the robot 1 into the vacuum chamber 30.

In the foregoing embodiment, description has been made on an instance where the robot 1 is a transfer robot for transferring a workpiece such as a glass substrate or a semiconductor wafer. Alternatively, the robot 1 may be a robot for performing a task other than the workpiece transfer. In the foregoing embodiment, description has been made on an instance where the robot 1 is installed in the vacuum chamber 30. However, the chamber in which the robot 1 is installed may be a chamber other than the vacuum chamber 30.

In the foregoing embodiment, description has been made on an instance where the carrying-in task is performed by hoisting the body unit 10 and the arm unit 20 with the ceiling crane 700 provided in a building or the like. However, the crane for use in the carrying-in task of the body unit 10 and the arm unit 20 may not be necessarily the ceiling crane 700.

In the foregoing embodiment, description has been made on an instance where the number of the extendible arms is two and each of the extendible arms includes a first arm and a second arm. However, the number of the extendible arms is not limited to two and each of the extendible arms may include an additional arm other than the first arm and the second arm.

Other effects and other modified examples can be readily derived by those skilled in the art. For that reason, the broad aspect of the present disclosure is not limited to the specific disclosure and the representative embodiment shown and described above. Accordingly, the present disclosure can be modified in many different forms without departing from the spirit and scope defined by the appended claims and the equivalents thereof.

What is claimed is:

1. A robot, comprising:
a base unit hoisted up from below a bottom surface portion of a chamber defining a work space and connected to the bottom surface portion of the chamber; and
an arm unit carried into the chamber from above the chamber and connected to an upper portion of the base unit connected to the bottom surface portion of the chamber.

2. The robot of claim 1, wherein the sum of a height of the base unit and a height of the arm unit is larger than a height of a carrying-in space formed above the chamber, the height of the base unit being smaller than a height from an installation surface of the chamber to the bottom surface portion of the chamber but being larger than the height of the carrying-in space.

3. A robot installation method, comprising:
a base unit connecting step of hoisting a base unit of a robot from below a bottom surface portion of a chamber defining a work space and having a unit-connecting opening formed in the bottom surface portion, and connecting the base unit to the bottom surface portion of the chamber while causing a connecting surface of the base unit to face toward the unit-connecting opening; and
an arm unit connecting step of carrying an arm unit of the robot into the chamber from above the chamber while causing the arm unit to face toward the connecting surface of the base unit through the unit-connecting opening, and connecting the arm unit to the base unit connected to the bottom surface portion of the chamber.

4. The method of claim 3, wherein the base unit is connected to the bottom surface portion of the chamber from below the bottom surface portion in the base unit connecting step and the arm unit is connected to the base unit from above the base unit in the arm unit connecting step.

5. The method of claim 3, wherein the base unit connecting step includes transferring the base unit to below the bottom surface portion of the chamber, hoisting up the base unit transferred to below the bottom surface portion of the chamber through the unit-connecting opening, and positioning the hoisted base unit with respect to the bottom surface portion of the chamber.

6. The method of claim 4, wherein the base unit connecting step includes transferring the base unit to below the bottom surface portion of the chamber, hoisting up the base unit transferred to below the bottom surface portion of the chamber through the unit-connecting opening, and positioning the hoisted base unit with respect to the bottom surface portion of the chamber.
